(19) United States
(12) Patent Application Publication
(10) Pub. No.: US 2010/0164768 A1
(43) Pub. Date: Jul. 1, 2010

(54) PROVIDING DIGITAL CODES REPRESENTING ANALOG SAMPLES WITH ENHANCED ACCURACY WHILE USING AN ADC OF LOWER RESOLUTION

(75) Inventors: Yujendra Mitikiri, Hyderabad (IN); Kiran Manohar Godbole, Bangalore (IN)

Correspondence Address: TEXAS INSTRUMENTS INCORPORATED, P O BOX 655474, M/S 3999, DALLAS, TX, 75265, US

(73) Assignee: TEXAS INSTRUMENTS INCORPORATED, Dallas, TX (US)

(21) Appl. No.: 12/346,858

(22) Filed: Dec. 31, 2008

(51) Int. Cl. H03M 1/12

(52) U.S. Cl. 341/132; 341/161

(57) ABSTRACT

An aspect of the present invention improves accuracy of output codes generated by a lower resolution ADC. In an embodiment, a gain factor is determined by examining a strength of an input signal in analog form. The gain factor equals one if the strength is more than half of the maximum voltage resolvable by the ADC and is more than one otherwise. An analog sample obtained from the input signal is converted to a digital code using the ADC, with the digital code being scaled up by the gain factor compared to an output code representing the strength of the analog sample in relation to the maximum voltage. The digital code is divided by the gain factor to generate the output code representing the strength of the analog sample in relation to the maximum voltage. The accuracy of the output code is greater for smaller amplitudes of the analog samples.

### BACKGROUND OF THE INVENTION

1. Technical Field

The present disclosure relates generating digital codes corresponding to the strength of the corresponding analog samples, and more specifically to providing such digital code with enhanced accuracy while using an ADC of lower resolution.

2. Related Art

An analog to digital converter (ADC) samples an analog signal received as input at corresponding (sampling) instants of time, and generates a sequence of digital codes representing the magnitude of the corresponding samples.

Accuracy of an ADC specifies how close the digital representation of a sample is compared to the actual amplitude of the sample. As is well known in the relevant arts, accuracy of an ADC may depend on various factors. One factor is the resolution of the ADC.

Resolution of an ADC is the smallest amplitude of a sample of an analog input that the ADC can accurately (without errors) represent in the form of a corresponding digital code, and is equal to the magnitude representable by the least significant bit (LSB) of the output digital code. In general, larger the number of bits in the digital code, larger is the ADC resolution. For example, a 16-bit ADC (16 bits of resolution) can, in general, represent analog samples with greater accuracy than an 8-bit ADC.

However, higher-resolution ADCs generally consume more power, require greater implementation area, and are more expensive. Several aspects of the present invention enable a conversion circuit to provide digital codes of enhanced accuracy while using an ADC of lower resolution.

### SUMMARY

An aspect of the present invention improves the accuracy of output codes generated by a lower resolution ADC. In an embodiment, a gain factor is determined by examining a strength of an input signal in analog form. The gain factor is then used to exploit the available range of the ADC.

In one embodiment, the input signal is amplified by the gain factor before being sampled and converted by the ADC to a corresponding digital code. A divider circuit then divides the digital code by the gain factor to generate a final output code.

In an alternative embodiment, a reference buffer attenuates a voltage signal (with a voltage equaling the maximum resolvable voltage by the ADC) by the gain factor and provides the attenuated voltage as the reference voltage to the ADC.

According to another aspect of the present invention, the output code contains more bits than the digital code generated by the ADC. In such an embodiment, the digital code is appended a number of zeroes as least significant bits, and the resulting number is right shifted by a number of positions equaling log to the base 2 of the gain factor. Thus higher accuracy is obtained using lower resolution ADC, at least in the case of smaller amplitude input signals.

Several aspects of the invention are described below with reference to examples for illustration. It should be understood that numerous specific details, relationships, and methods are set forth to provide a full understanding of the invention. One skilled in the relevant art, however, will readily recognize that the invention can be practiced without one or more of the specific details, or with other methods, etc. In other instances, well-known structures or operations are not shown in detail to avoid obscuring the features of the invention.

### BRIEF DESCRIPTION OF THE DRAWINGS

Example embodiments of the present invention will be described with reference to the accompanying drawings briefly described below.

FIG. 1A is a block diagram of a conversion circuit in an embodiment of the present invention.

FIG. 1B is a timing diagram illustrating clock signals generated in an embodiment of the present invention.

FIG. 2A is a graph illustrating enhanced accuracy obtainable according to an aspect of the present invention.

FIG. 2B is a table showing values of various parameters and signals in a conversion circuit in an embodiment of the present invention.

FIG. 3A is a diagram of a transfer curve of a conversion circuit, in an embodiment of the present invention.

FIG. 3B is a diagram of a transfer curve of an ADC, in a prior embodiment.

FIG. 4 is a block diagram of a conversion circuit in an alternative embodiment of the present invention.

FIG. 5 is a block diagram of a system/device in which several aspects of the present invention may be implemented.

In the drawings, like reference numbers generally indicate identical, functionally similar, and/or structurally similar elements. The drawing in which an element first appears is indicated by the leftmost digit(s) in the corresponding reference number.

### DETAILED DESCRIPTION

The features of the present invention are described below with several examples for illustration.

1. Conversion Circuit

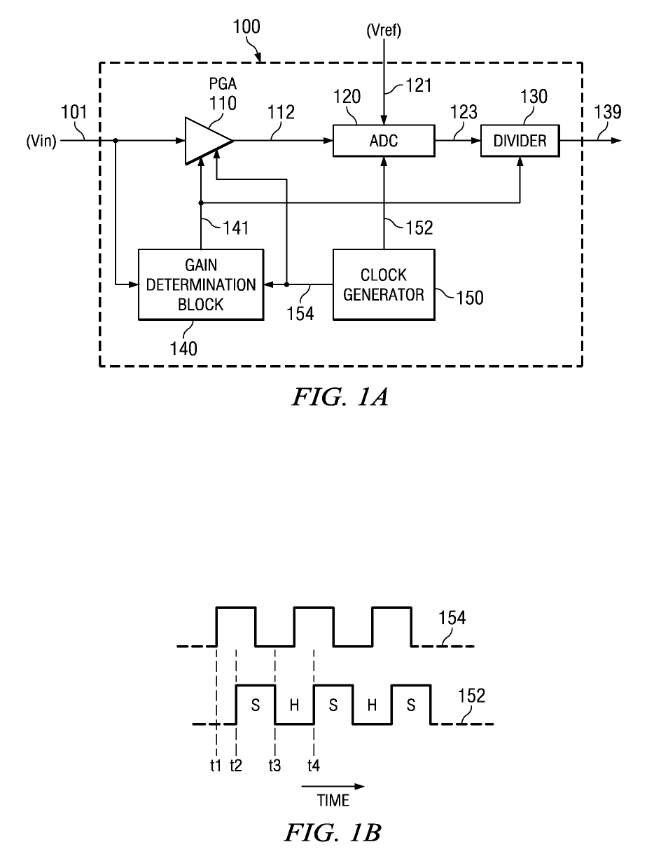

FIG. 1A is a block diagram of a conversion circuit in an embodiment of the present invention. Conversion circuit 100 is shown containing programmable gain amplifier (PGA) 110, ADC 120, divider 130, gain determination block 140, and clock generator 150. The specific components/blocks of FIG. 1A are shown merely by way of illustration, and several features of the present invention can be implemented using other types and combinations of components as well.

Clock generator 150 provides clock 152 to ADC 120, and clock 154 to each of gain determination block 140 and PGA 110. FIG. 1B shows portions of clock signals 152 and 154, in an embodiment of the present invention. Clock signal 152 specifies sample and conversion time intervals (marked as ‘S’ and ‘H’ respectively) of ADC 120, to sample and convert signal 112. ADC 120 may begin sampling signal 112 at every rising edge of clock 152, the sampling interval ending at the next falling edge. ADC 120 may begin conversion of the corresponding sample at every falling edge of clock 152, the conversion interval ending at the next rising edge. For example, a sample generated by sampling signal 112 during sampling interval t2-t3 may be converted into a corresponding digital code during the subsequent hold interval t3-t4.

Clock 154, provided to each of gain determination block 140 and PGA 110, is earlier in phase compared to clock 152. Gain determination block 140 may examine (measure) the strength of input 101 at each rising edge of clock 154 (e.g., t1), and provide (with a small delay) the gain factor at a time instance earlier than the next sampling edge of clock 152 (e.g., t2). PGA 110 is designed such that the gain is provided (and maintained stable) before the next sampling edge of clock 152. Thus, the total delay in gain determination block 140 and PGA in providing a (new) gain value is ensured to be less than the interval t1-t2. According to an aspect of the present invention, a single digital code is generated in each clock cycle of clock 152.

PGA 110 receives an analog signal on path 101, and provides a gained (amplified) version of signal 101 on path 112, with the gain being specified by gain determination block 120 via path 141.

ADC 120 receives amplified analog signal 112, and generates digital codes representing the amplitudes of samples generated at corresponding sampling instances (specified by clock 152). ADC 120 may be implemented using technologies such as SAR or pipeline ADCs, well known in the relevant arts. ADC 120 receives a reference voltage (Vref) on path 121, which may determine the full-scale range (and maximum resolved voltage, Vmax) of ADC 120. ADC 120's full-scale range (also termed dynamic range) refers to the total range of input (112) amplitudes that the ADC can resolve accurately, and is usually expressed in decibels (dB).

Vref (121) may be provided by a reference voltage source (not shown) contained within conversion circuit 100, or provided externally. The magnitude of Vref represents the maximum voltage that ADC 120 can resolve at that time instance, and the output code in such situations equals the maximum digital output.

A high dynamic range may be of importance in several applications, such as those in which input signal strengths may exhibit a wide amplitude range. Accordingly, in an embodiment of the present invention, the value of Vref (121) (in volts) is selected to be high. While such a high value enables ADC 120 to resolve analog samples of larger magnitudes, an aspect of the present invention enables the sample of small amplitudes to be resolved with greater accuracy as described below.

Gain determination block 140 examines the strength of input signal 101 (i.e., in analog form), and determines a gain value for amplifying input 101, as noted above. Gain determination block 140 provides the gain value to both PGA 110 and divider 130. The gain value may be determined to make effective use of the dynamic range of ADC 120. In general, the gain value is higher for smaller amplitudes of input signal 101. It may also be appreciated from the description above that gain values are determined based on a ratio of Vref (“maximum voltage”) and the strength of input signal 101. Further, it may also be appreciated that, the application of a gain factor other than one, would cause an analog sample to be gained to a value whose ratio with respect to Vref would be different had the gain not be applied (gain equals one).

In an embodiment, gain determination block 140 is implemented as a flash ADC containing as many comparators internally as the number of gain settings desired. Consistent with the design of divider 130 implemented as a shifter, gain determination block 140 is designed to check whether the sample of the input signal is less than ½¹, ½², ½³, etc., (in general fractions equaling powers of two) of the maximum strength (“maximum resolvable strength”, generally equaling Vref) that ADC 120 is designed to resolve. The provided gain value equals the inverse of the fraction corresponding to the comparator with the least threshold indicating that the input signal has lesser strength. For example, if the sampled strength is ⅔, ⅓, ⅕ and 1/9 of the maximum resolved strength, the gain value would equal 1 (no gain), 2, 4 and 8 respectively.

In general, the number of gain settings may be based on the specific type/source and/or characteristics of input signal 101. Gain determination block 140 may also be implemented using other techniques (not limited to shifting in divider 130), as will be apparent to one skilled in the relevant arts by reading the disclosure provided herein.

Divider 130 divides each digital code (123) by the gain value using which the corresponding analog signal was earlier amplified by PGA 110. In an embodiment, divider 130 is implemented as a shifter, which first appends lesser significant bits (LSBs) to output 123 received from ADC 120, and (internally) forms an intermediate output code. Divider 130 right-shifts the intermediate output code by a number of bit-shifts corresponding to the gain value 141 specified by gain determination block 140. For example, if the gain value is 4, a right shift by 2 bits (in general, log to base 2 of the gain value) may be performed.

Assuming for illustration that conversion circuit 100 is implemented to provide a 5-bit output (on path 139), and two possible values of gain (gain value of 1 and gain value of 2) for PGA 110 are specified, ADC 120 may be implemented as a 4-bit ADC. Divider 130 appends a 5^{th} bit (in the LSB position) to each 4-bit output of ADC 120. Assuming that the gain value corresponding to a sample ‘A’ is one, and the 4-bit output of ADC 120 corresponding to the sample is 0101 (binary), divider appends a 0 (binary) as the LSB to (0101) to form (01010). Since the gain value was one, divider 130 performs no right shift (right shift by zero bits), and provides (01010) as the output code on path 139.

If a gain value of two is applied, the 4-bit output of ADC 120 may be 1010 (binary), divider 130 appends a 0 (binary) as the LSB to (1010) to form (10100). Since the gain value was two, divider 130 right shifts (10100) by one bit (equivalent to divide by 2), and provides (00101) as the output code on path 139. For a gain value not equal to one, it may be observed that digital code 123 provided by ADC 120 is ‘scaled up’ by the gain factor (which is related by a factor to Vref, the maximum voltage) compared to output code 139 provided to represent the strength of the analog sample.

Conversion circuit 100, implemented in a manner described above, provides digital codes (139) representing analog samples of analog signal 101 with enhanced accuracy, while still employing an ADC (ADC 120) of lower resolution. Such enhanced accuracy using a lower resolution ADC based on the approach described above, is illustrated next with an example.

2. Example Illustrating Enhanced Accuracy

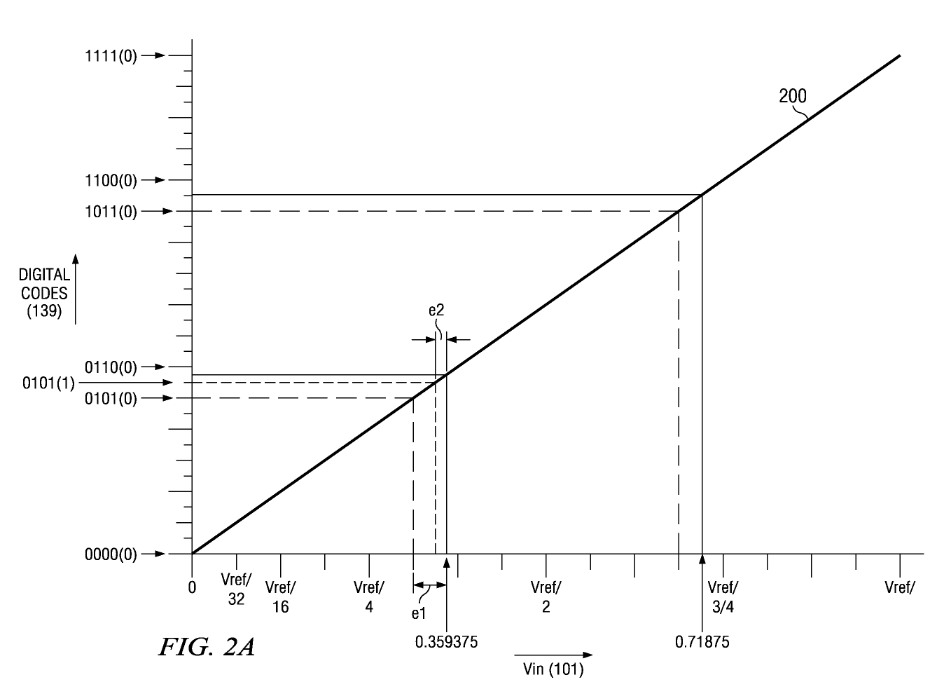

FIG. 2A is a graph illustrating enhanced accuracy obtainable according to an aspect of the present invention. Vin (path 101) amplitudes are shown along the X axis, while the corresponding digital codes are shown along the Y axis. Straight line 200 represents the (ideal) transfer curve of ADC 120 (as well as of conversion circuit 100). The more significant 4 bits of each digital code (139) are generated by ADC 120, while the fifth bit is formed by divider 130, as described above. The example below is provided merely by way of illustration, and assumes that the output code (path 139) is 5-bit wide, ADC 120 is a 4-bit ADC, and only two gain values (1 and 2) are provided by gain determination block 140

With the assumption that ADC 120 is a 4-bit ADC, the value of the least significant bit (LSB) of 4-bit output (123) is Vref/16. Divider 130 appends the LSB of output code 139, as described above. Input (101) in the example is assumed to have a magnitude of ( 23/64*Vref), i.e. 0.359375 times Vref.

Assuming that the threshold within gain determination block 140 is implemented such that the value of input ( 23/64*Vref) corresponds to a gain value of one (1) being generated for PGA 110, the output of PGA 110 will also be ( 23/64*Vref). Since LSB value of ADC 120 is Vref/16, input 112 to ADC corresponds to value of 5.75 times the value representable by ADC 120's LSB, i.e., (5.75*LSB). Therefore, ADC 120 generates a 4-bit output 0101 (decimal value of 5) on path 123, representing the decimal portion of the input value 5.75*LSB.

Divider 130 appends a zero to the 4-bit value (0101) received on path 123. Since the gain value of PGA 110 is set as one (also indicated to divider 130 on path 141), divider 130 does not perform any right shift, and provides a 5-bit output (01010). Thus, an input of ( 23/64*Vref) generates a code 01010. The resulting error is denoted in the Figure by e1, and equals (0.0468*Vref). It is noted that the value of (0.0468*Vref) is obtained as the difference of the input analog value (0.359375*Vref) and the value 0.3125 Vref, i.e., 10/32 times Vref) corresponding to the provided code (01010).

However, if the threshold within gain determination block 140 is implemented such that the value of input ( 23/64*Vref) corresponds to a gain value of two (2) being generated for PGA 110, the output of PGA 110 will be ( 23/32*Vref), i.e., (0.71875*Vref). Since LSB value of ADC 120 is Vref/16, input 112 to ADC now (with gain of 2) corresponds to 11.5 times the value representable by ADC 120's LSB, i.e., (11.5*LSB). Therefore, ADC 120 generates a 4-bit output 1011 (decimal value of 11) on path 123, representing the decimal portion of the input value (11.5*LSB).

Divider 130 appends a zero to the 4-bit value (1011) received on path 123, and forms an intermediate output code 10110. Since the gain value of PGA 110 is set as two (also indicated to divider 130 on path 141), divider 130 right shifts (10110) by one bit, and provides a 5-bit output (01011). Thus, with a gain setting of two an input of ( 23/64*Vref) generates a code 01011. The resulting error is denoted in the Figure by e2, and equals (0.015625*Vref). It is noted that the value of (0.015625*Vref) is obtained as the difference of the input analog value (0.359375*Vref) and the value 0.34375*Vref, i.e., 11/32 times Vref) corresponding to the provided code (01011).

It may be observed that e2 is smaller than e1. In general, higher gain values, followed by the corresponding number of right shifts, provides output codes which are more accurate. The errors noted above are due to quantization errors inherent in ADC 120. In addition, the approach described above, also reduces error contributions from other sources, such as non-linearity errors, offset errors, gain errors, etc., of ADC 120.

To illustrate using the same example input value as above, assuming the total error contribution to all non-quantization related error sources put together is 0.375*LSB (of ADC 120), with a gain value of 1 for PGA 110, ADC 120's output (123) will be 0110, and output (139) would be 01100. On the other hand, with a gain value of 2 for PGA 110, ADC 120's output would be 1011, and output (139) would be 01101. Therefore, the above approach, results in reduction due to non-quantization errors of ADC 120 as well.

It may also be observed from the example above, that when the gain is two, input sample corresponding to the value ( 23/64*Vref) is resolved as a different ratio ( 23/32*Vref) by ADC 120.

In an embodiment, ADC 120 is implemented as a unipolar 14-bit SAR ADC using switched capacitor techniques (and receives only positive values of analog input signal), and conversion circuit 100 provides an 18-bit output code (139). Conversion circuit 100 is designed to operate using five (5) accuracy levels, with the highest accuracy being provided for the lowermost (smallest signal amplitude range) of the 5 input sub-ranges, and the least accuracy for th highest of the sub-ranges. PGA 110 is implemented in the embodiment using switched capacitor techniques.

In an embodiment, gain determination block 140, implemented as a flash ADC, is designed to have four comparators, with the respective comparators having their comparison threshold voltages equal to (+ 3/64*Vref), (+ 3/32*Vref), (+ 3/16*Vref) and (+⅜*Vref). FIG. 2B shows a table with rows 291-295 specifying the comparator outputs of the flash ADC (column 250), input signal sub-ranges (column 260), PGA gain (column 270), and the bit-append-and right-shift operations for each of the corresponding sub-ranges. Corresponding to each of the sub-ranges, bits 1 through 18 of output 139 (Dout<1:18>) are obtained by appending four zeros to the 14-bit output (ADC<1:14>) of ADC 120, followed by the corresponding number of right shifts. For each right shift, a zero is shifted in to the most significant position (bit 18) of output 139.

In another embodiment, gain determination block 140 (implemented again as a flash ADC) is designed to contain four comparators, each with reduced precision to reduce implementation cost. The switching threshold of each of the comparators rather than being a single precise threshold is instead a range of values (due to the low-cost, low precision implementation of the comparators). In one embodiment, the respective comparators have their thresholds respectively in the ranges [+Vref/32, +Vref/16], [+Vref/16, +Vref/8], [+Vref/8, +Vref/4], [+Vref/4, +Vref/2]. The ranges, and sub-ranges noted above are merely illustrative, and other ranges, sub-ranges can also be employed in other embodiments.

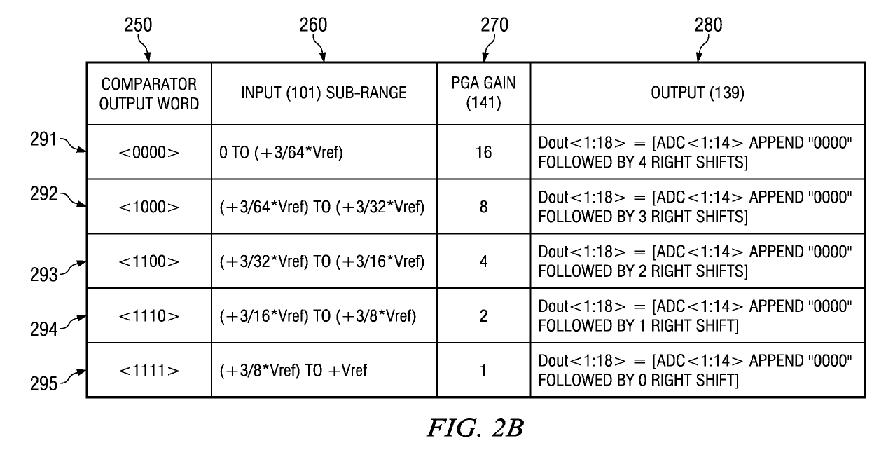

FIG. 3A is a diagram illustrating the (ideal) transfer curve of a conversion circuit implemented in the manner described above. Four regions (input sub-ranges) 310, 320, 330, 340 and 350 of transfer curve 300 of a conversion circuit are shown, with the errors (shown shaded in the Figure) in the output codes for inputs in the portions corresponding to 350, 340, 330, 320 and 310 being successively smaller, thereby providing output codes for inputs in region 310 with highest accuracy, and inputs in region 350 with the least accuracy. Arrows 305 and 306 depict the maximum possible error (positive or negative) for region 340, while arrows 303 and 304 depict the maximum possible error (positive or negative) for region 330. Variations in accuracy among regions 310-350 varies in a linear fashion. An ADC with a smaller resolution may be used in the conversion circuit to provide the enhanced accuracy by gaining smaller amplitude inputs appropriately, in a manner described above.

FIG. 3B is a diagram of an ideal transfer curve 360 of a prior ADC that does not use the approach of the present invention. It may be observed that the ADC provides a substantially constant accuracy (and therefore error) for all amplitudes of input signal. Arrows 351 and 352 depict the maximum possible error (positive or negative) for any amplitude of analog input signal. For applications that require high accuracy, the ADC may need to be implemented directly as a high-resolution ADC, with a large number of output bits. The attendant drawbacks of such implementations have been noted above.

It is noted that the approach of FIG. 1A above assumes negligible error in PGA 110. However, PGA 110, being a continuous-time amplifier, can be implemented to have much lesser error than a corresponding ADC, and therefore the above assumption is valid. PGA 110 may be implemented to be a highly accurate and linear amplifier using well-known techniques.

In an alternative embodiment of the present invention, the value of a reference voltage provided to an ADC (to perform digital to analog conversion) is adjusted rather than scaling the input signal by a PGA (as in FIG. 1A). Accordingly, such an alternative approach is described next.

3. Varying the Reference Voltage Magnitude

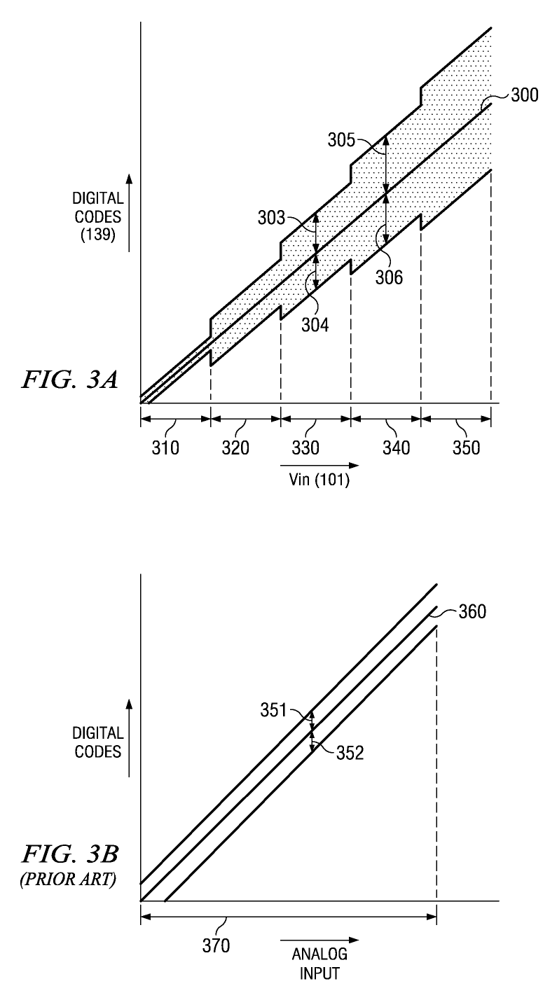

FIG. 4 is a block diagram of a conversion circuit in another embodiment of the present invention. Conversion circuit 400 of FIG. 4 is shown containing reference buffer 410, ADC 420, divider 430, gain determination block 440, and clock generator 450. Input signal 101 is directly provided to ADC 420. Voltage 401 (either generated within conversion circuit 400, or provided from an external source), having a fixed strength, is provided to reference buffer 410.

ADC 420, divider 430, and clock generator 450 operate similar to ADC 120, divider 130, and clock generator 150 of FIG. 1A, and their description is not repeated here in the interest of conciseness.

Reference buffer 410 gains a reference voltage (Vref) 401 by a gain factor received on path 441, and provides the gained voltage signal as reference voltage 421 to ADC 420. As noted above with respect to FIG. 1, Vref (401) represents the maximum signal amplitude that ADC 420 can resolve. Reference buffer 410 may be implemented using any of well known techniques, including switched capacitor techniques.

Gain determination block 440 controls (via path 441) the gain of reference buffer 410. The gain factor (or attenuation factor) is determined using techniques similar to that in block 140, except that the gain factor provided on path 441 would be the inverse (one divided by gain factor) of that provided on path 141, for the same magnitude of the input sample.

By adjusting the gain of reference buffer based on the amplitude of input signal 101, benefits similar to that noted with respect to conversion circuit 100 (FIG. 1A) may be obtained. The attenuation provided by reference buffer 410 is adjusted to be greater to obtain greater accuracy (in case of smaller amplitude samples), and smaller (or no attenuation) for lesser accuracy (in case of larger amplitude samples).

As a result, ADC 420 would operate with a smaller magnitude of reference voltage 421 in case of smaller amplitude samples, and a larger magnitude of reference voltage 421 signal in case of larger amplitude samples. Thus, the error analysis would have a similar shape as that described with respect to FIGS. 2A and 3A above.

Again, similar to the embodiment of FIG. 1A, it may be appreciated that, the application of an attenuation factor other than one, would cause an analog sample to be resolved as a value whose ratio with respect to reference voltage 421 would be different than if the attenuation were not applied (or equals one). Also, for attenuation factors not equal to one, it may be observed that digital codes provided by ADC 420 are ‘scaled up’ in relation to reference voltage 421 (reference voltage 421 being attenuated), compared to output codes provided to represent the strength of the analog sample.

Thus, several features of the present invention enable a lower resolution ADC to be employed to enhance the accuracy with which digital codes may represent analog sample values.

As is well-known, the measurement of signals generated by several sources may require a high dynamic range, but may not necessarily require a high resolution. Voice signals are an example of such signal sources. While a high resolution ADC with a high dynamic range (example transfer curve shown in FIG. 3B) may be used for meeting the above noted objective, such an approach may have the disadvantages of higher cost, power consumption and complexity, as also noted above.

A conversion circuit implemented as described above overcomes such disadvantages. The accuracy obtainable for the corresponding input sub-ranges in such a conversion circuit varies linearly, but may also be viewed as varying logarithmically if the accuracy variation is measured with respect to the total number of output codes expressed as a power of 2. To clarify, assuming an 18 bit output code, and a 14-bit ADC, the absolute error in the final output varies linearly with the input as 16*Vin/Vref LSB, but measured as a power of 2, the error is of the order [4+log₂(Vin/Vref)].

A conversion circuit implemented as described above may be incorporated in a device/system, as illustrated next with an example.

4. System/Device

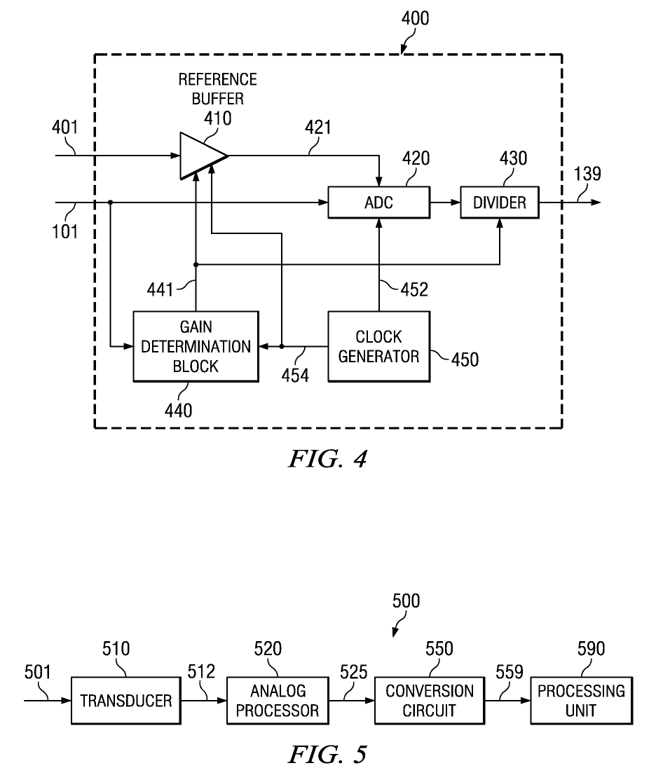

FIG. 5 is a block diagram of a system (500), illustrating an example system in which several aspects of the present invention may be implemented. System 500, which may correspond to, for example, a voice or sound processing system, is shown containing transducer 510, analog processor 520, conversion circuit 550, and processing unit 590.

Transducer 510 receives analog signals (for example human voice, sound, etc) in non-electrical form on path 501, and operates to generate electrical signals representing the received analog signals. The electrical signals may be provided to analog processor 520 on path 512 for further processing. Analog processor 520 may perform tasks such as amplification (or attenuation as desired), filtering, etc., on received signals, and provides the resulting signal on path 525.

Conversion circuit 550 converts the analog signal received on path 525 to corresponding digital codes at a sampling frequency. Conversion circuit 550 may be implemented using a comparatively low resolution ADC, and providing at least some ranges of input signal amplitudes with higher accuracy, and implemented according to the approaches described above. Conversion circuit 550 provides the digital codes to processing unit 590 on path 559 for further processing. Processing unit 590 processes the digital codes received on path 559 to provide various desired features.

While various embodiments of the present invention have been described above, it should be understood that they have been presented by way of example only, and not limitation. Thus, the breadth and scope of the present invention should not be limited by any of the above-described embodiments, but should be defined only in accordance with the following claims and their equivalents.

What is claimed is:

1. A conversion circuit to generate output codes representing a strength of samples on an input signal, said conversion circuit comprising:
an analog to digital converter (ADC) to generate a digital code representing a strength of an analog sample according to a reference voltage, said sample being obtained based on said input signal and having a first ratio with a maximum voltage said ADC is designed to resolve;
a gain determination block to examine said input signal in analog form and to determine a gain factor based on a ratio of said maximum voltage and the strength of said input signal,
said gain determination block to cause said analog sample to be resolved as a second ratio with said maximum voltage, wherein said first ratio is not equal to said second ratio; and
a divider to generate an output code representing the strength of said analog sample by dividing said digital code by said gain factor.

2. The conversion circuit of claim 1, wherein said first ratio is less than or equal to 0.5 such that said strength of said analog sample is less than or equal to half of said maximum voltage, said digital code having a value greater than said output code.

3. The conversion circuit of claim 2, said ADC to sample a second analog sample having a strength with a ratio more than 0.5 with respect to said maximum voltage, said gain determination block to set said gain factor equal to 1.

4. The conversion circuit of claim 1, wherein said digital code has fewer bits than said output code.

5. The conversion circuit of claim 4, wherein said gain factor equals a power of 2, wherein said divider comprises a shifter to append a number of zeros as least significant bits to said digital code to form an intermediate code having a same number of bits as said output code,
said shifter to shift right said intermediate code by a number of positions equaling a log to base 2 of said gain factor.

6. The conversion circuit of claim 5, wherein said gain determination block comprises a flash ADC and said ADC is a SAR ADC implemented according to switched capacitor techniques.

7. The conversion circuit of claim 1, wherein said gain determination block provides a corresponding gain factor for each of a sequence of output codes generated by said conversion circuit.

8. The conversion circuit of claim 1, further comprising:
a programmable gain amplifier to receive said gain factor and to amplify said input signal, wherein said ADC samples said analog sample from the amplified input signal.

9. The conversion circuit of claim 1, further comprising:
a reference buffer to receive said gain factor and to attenuate a voltage signal with said maximum strength by said gain factor to generate said reference voltage.

10. An article of manufacture comprising:
a conversion circuit to generate output codes representing a strength of samples on an input signal, said conversion circuit comprising:
an analog to digital converter (ADC) to generate a digital code representing a strength of an analog sample according to a reference voltage, said sample being obtained based on said input signal and having a first ratio with a maximum voltage said ADC is designed to resolve;
a gain determination block to examine said input signal in analog form and to determine a gain factor based on a ratio of said maximum voltage and the strength of said input signal,
said gain determination block to cause said analog sample to be resolved as a second ratio with said maximum voltage, wherein said first ratio is not equal to said second ratio; and
a divider to generate an output code representing the strength of said analog sample by dividing said digital code by said gain factor.

11. The article of manufacture of claim 10, wherein said first ratio is less than or equal to 0.5 such that said strength of said analog sample is less than or equal to half of said maximum voltage, said digital code having a value greater than said output code.

12. The article of manufacture of claim 11, said ADC to sample a second analog sample having a strength with a ratio more than 0.5 with respect to said maximum voltage, said gain determination block to set said gain factor equal to 1.

13. The article of manufacture of claim 10, further comprising:
a programmable gain amplifier to receive said gain factor and to amplify said input signal, wherein said ADC samples said analog sample from the amplified input signal.

14. The article of manufacture of claim 10, further comprising:
a reference buffer to receive said gain factor and to attenuate a voltage signal with said maximum strength by said gain factor to generate said reference voltage.

15. The article of manufacture of claim 13, further comprising:
a transducer to generate electrical signals representing analog signals received in non-electrical form;
an analog processor to generate said input signal from said electrical signal; and
a processor to process said output codes.

16. A conversion circuit to generate a sequence of output codes representing strength of an input signal at respective time instances using an analog to digital converter (ADC) designed to resolve a maximum voltage, said conversion circuit comprising:
means for determining a gain factor by examining a strength of said input signal in analog form, said gain factor equaling one if said strength is more than half of said maximum voltage and being more than one otherwise;
means for converting an analog sample obtained from said input signal to a digital code using said ADC, wherein said digital code is scaled up by said gain factor compared to an output code corresponding to the strength of said analog sample in relation to said maximum voltage; and
means for dividing said digital code by said gain factor to generate said output code.

17. A method of generating a sequence of output codes representing strength of an input signal at respective time instances using an analog to digital converter (ADC) designed to resolve a maximum voltage, said method comprising:
determining a gain factor by examining a strength of said input signal in analog form, said gain factor equaling one if said strength is more than half of said maximum voltage and being more than one otherwise;
converting an analog sample obtained from said input signal to a digital code using said ADC, wherein said digital code is scaled up by said gain factor compared to an output code corresponding to the strength of said analog sample in relation to said maximum voltage; and
dividing said digital code by said gain factor to generate said output code.

18. The method of claim 17, wherein said gain factor equals a power of two, and wherein said output codes have more number of bits compared to the digital code generated by said converting, wherein said dividing comprises:
adding a number of zeros as least significant bits to said digital code to generate an intermediate code, wherein said number of zeroes equals a different of the number of bits in said output code and said digital code; and
shifting right said intermediate code by a number of positions equaling log to the base 2 of said gain factor.

19. The method of claim 18, further comprising:
amplifying said input signal by said gain factor; and
providing the amplified input signal as an input to said ADC to perform said converting.

20. The method of claim 18, further comprising:
attenuating a voltage signal of said maximum voltage by said gain factor; and
providing the attenuate voltage signal as a reference voltage to said ADC to perform said converting.
